(19) United States
(12) Patent Application Publication
(10) Pub. No.: US 2010/0297806 A1
(43) Pub. Date: Nov. 25, 2010

(54) METHOD OF MANUFACTURING SOLAR CELL MODULE

(75) Inventor: Tatsuya Kiriyama, Hashima-gun (JP)

Correspondence Address: DITTHAVONG MORI & STEINER, P.C., 918 Prince Street, Alexandria, VA, 22314, US

(73) Assignee: SANYO ELECTRIC CO., LTD., Moriguchi-shi (JP)

(21) Appl. No.: 12/783,895

(22) Filed: May 20, 2010

(30) Foreign Application Priority Data
May 22, 2009 (JP) 2009-124261

(51) Int. Cl. H01L 31/18

(52) U.S. Cl. 438/80; 257/E21.347

(57) ABSTRACT

While using the same laser device, a slit (S4) is formed by cutting an photoelectric conversion unit and a backside electrode formed over a transparent electrode to a surface of the transparent electrode and a slit (S5) is formed by cutting the photoelectric conversion unit and the backside electrode formed in a slit (S2) of the transparent electrode in a direction intersecting a direction of the slit S4.

### CROSS-REFERENCE TO RELATED APPLICATIONS

The disclosure of Japanese Patent Application No. 2009-124261 filed on May 22, 2009, including specification, claims, drawings, and abstract, is incorporated herein by reference in its entirety.

### BACKGROUND

1. Technical Field

The present invention relates to a method of manufacturing a solar cell module.

2. Related Art

Solar cell modules are known in which semiconductor thin films such as amorphous and microcrystalline semiconductor thin films are layered. In particular, a solar cell module in which microcrystalline silicon or amorphous silicon thin film is used has attracted much attention in view of resource consumption, reduction of cost, and improvement in efficiency.

FIG. 3 is a cross sectional schematic diagram of a basic structure of a solar cell module 100. The solar cell module 100 generally has a structure in which a transparent electrode 12, an photoelectric conversion unit 14, and a backside electrode 16 are layered over a transparent substrate 10 such as glass, and generates power by incident of light through the transparent substrate 10.

A manufacturing method and a patterning device for integrating such solar cell modules in series are known in various references. For example, a configuration is known in which, during patterning with a laser, the structure is processed while gas is blown onto the structure.

FIGS. 4A-4F show a manufacturing process of the solar cell module 100 in related art. FIGS. 4A-4F schematically show plan views and cross sectional views in the steps of the manufacturing process of the solar cell module 100. The cross sectional views are cross sectional views along a line A-A in the plan view and cross sectional views along a line B-B in the plan view.

In step S10, as shown in FIG. 4A, through laser patterning, a slit S1 which divides the transparent electrode 12 formed over the transparent substrate 10 is formed, and a slit S2 is formed in a direction perpendicular to the slit S1. In step S12, as shown in FIG. 4B, a film of the photoelectric conversion unit 14 is formed covering the transparent electrode 12. As the photoelectric conversion unit 14, an amorphous silicon (a-Si) photoelectric conversion unit, a microcrystalline silicon (μc-Si) photoelectric conversion unit, or a tandem structure of these units may be employed. In step S14, as shown in FIG. 4C, through laser patterning, a slit S3 which divides the photoelectric conversion unit 14 is formed at a position near the slit S1 and not overlapping the slit S1, along the direction of the slit S1. In step S16, as shown in FIG. 4D, the backside electrode 16 is formed covering the photoelectric conversion unit 14. Instep S18, as shown in FIG. 4E, through laser patterning, a slit S4 which divides the photoelectric conversion unit 14 and the backside electrode 16 is formed at a position near the slit S3 and not overlapping the slits S1 and S3, along the direction of the slits S1 and S3. With such a process, a structure is obtained in which a plurality of solar cells are connected in series along the direction of the slit S2. In step S20, as shown in FIG. 4F, through laser patterning, a slit S5 which divides the photoelectric conversion unit 14 and the backside electrode 16 formed in the slit S2 is formed. As a result, a structure is obtained in which solar cells which are adjacent to each other along the direction of the slit S1 are electrically separated from each other and a plurality of groups of solar cells each comprising a plurality of solar cells connected in series are provided in parallel to each other. The groups of solar cells are ultimately connected in parallel with each other, and the solar cell module 100 is formed.

A laser device for patterning the slits S3 and S4 is made for integrating a large number of solar cells in series along the direction of the slit S2, and typically is not suited for patterning in a direction perpendicular to the directions of the slits S3 and S4.

For example, the laser device for patterning the slits S3 and S4 has a rectangular laser beam shape, and, because the optimum values for the patterning conditions for dividing the photoelectric conversion unit 14 and the backside electrode 16 differ between the direction along the slits S3 and S4 and the direction perpendicular to this direction, it has been difficult to find an optimum patterning condition in both dividing directions.

In addition, in the laser device for patterning the slits S3 and S4, in order to simultaneously form the plurality of slits S3 and S4 in the direction of integration of the solar cells for the purpose of improving the patterning speed, a plurality of laser beam emission holes are placed at equal spacing, and, when the patterning in the direction perpendicular to the slits S3 and S4 is executed, a plurality of laser beam patterning lines overlap each other, and, thus, the laser device is not suited for patterning the slit S5.

Because of this, the slit S5 in the direction perpendicular to the slit S4 cannot be formed by the laser device for forming the slit S4, and the laser device must be changed at steps S18 and S20, which results in a problem in that the time required for manufacturing is increased.

### SUMMARY

According to one aspect of the present invention, there is provided a method of manufacturing a solar cell module comprising a first step in which a transparent conductive film formed over a substrate is cut using a first laser device in a first direction to form a first channel and in a second direction intersecting the first direction to form a second channel; a second step in which an photoelectric conversion film formed over the transparent conductive film is cut using a second laser device along the first direction and to a surface of the transparent conductive film to form a third channel; and a third step in which the photoelectric conversion film and an electrode film formed over the transparent conductive film are cut using a third laser device along the first direction and to the surface of the transparent conductive film to form a fourth channel, and the photoelectric conversion film and the electrode film formed in the second channel are cut using the third laser device along the second direction to form a fifth channel.

### BRIEF DESCRIPTION OF THE DRAWINGS

A preferred embodiment of the present invention will be described in further detail based on the following drawings, wherein:

FIG. 1A is a plan view and cross sectional views showing a step S30 of a manufacturing process of a solar cell module according to a preferred embodiment of the present invention;

FIG. 1B is a plan view and cross sectional views showing a step S32 of the manufacturing process of the solar cell module according to the preferred embodiment of the present invention;

FIG. 1C is a plan view and cross sectional views showing a step S34 of the manufacturing process of the solar cell module according to the preferred embodiment of the present invention;

FIG. 1D is a plan view and cross sectional views showing a step S36 of the manufacturing process of the solar cell module according to the preferred embodiment of the present invention;

FIG. 1E is a plan view and cross sectional views showing a step S38 of the manufacturing process of the solar cell module according to the preferred embodiment of the present invention;

FIG. 2 is a diagram for explaining a spot of a laser beam emitted from a laser device in the preferred embodiment of the present invention;

FIG. 3 is a diagram showing a basic structure of a solar cell module;

FIG. 4A is a plan view and cross sectional views showing a step S10 of a manufacturing process of a solar cell module in the related art;

FIG. 4B is a plan view and cross sectional views showing a step S12 of the manufacturing process of the solar cell module in the related art;

FIG. 4C is a plan view and cross sectional views showing a step S14 of the manufacturing process of the solar cell module in the related art;

FIG. 4D is a plan view and cross sectional views showing a step S16 of the manufacturing process of the solar cell module in the related art;

FIG. 4E is a plan view and cross sectional views showing a step S18 of the manufacturing process of the solar cell module in the related art; and

FIG. 4F is a plan view and cross sectional views showing a step S20 of the manufacturing process of the solar cell module in the related art.

### DETAILED DESCRIPTION

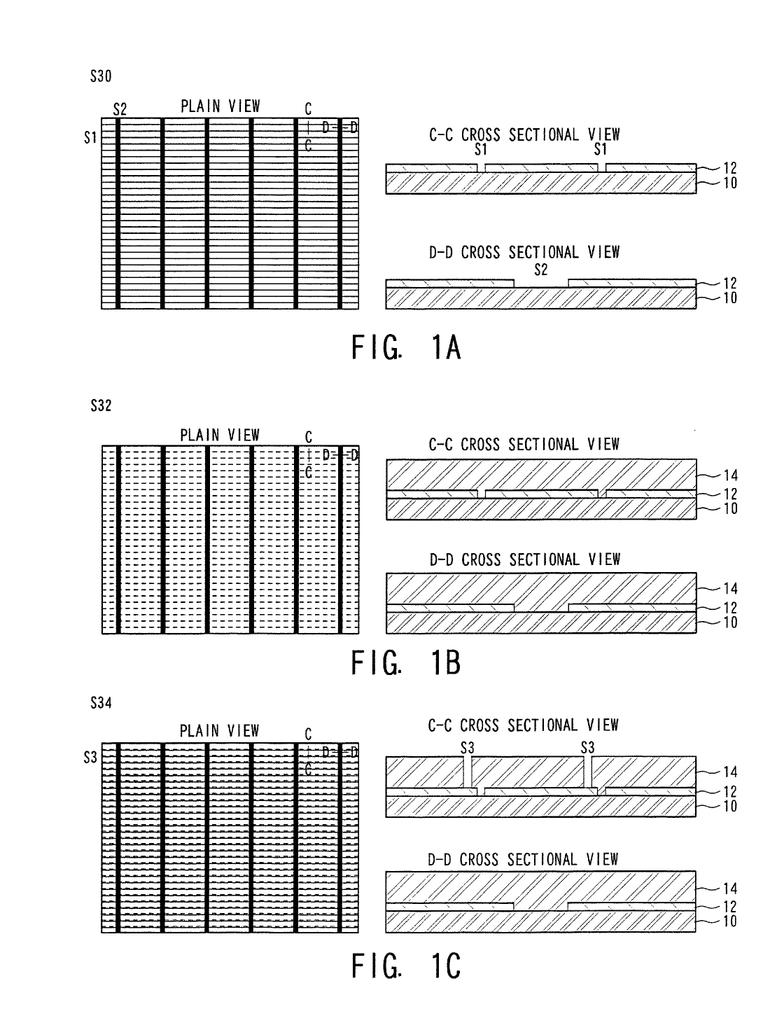

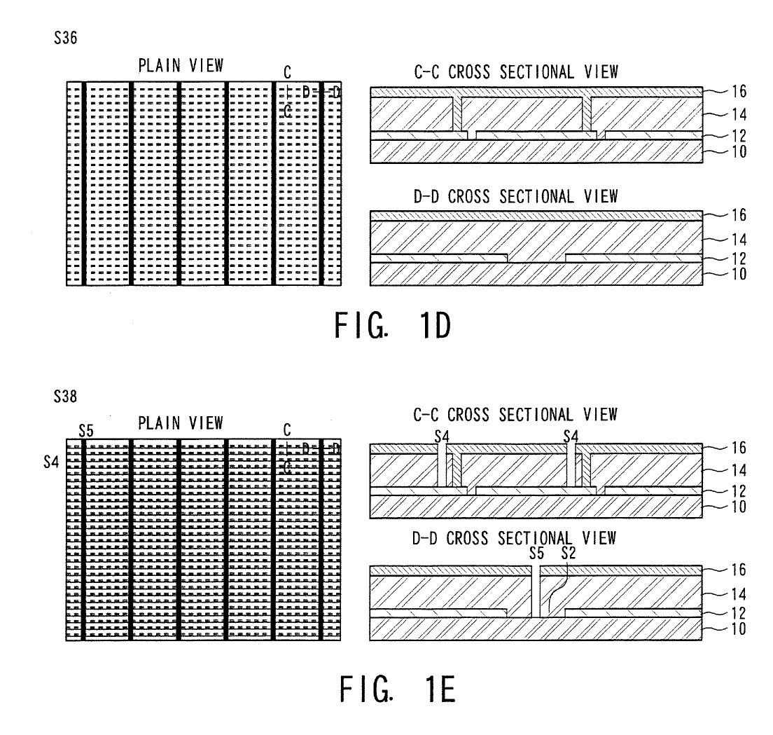

FIGS. 1A-1E show a manufacturing process of a solar cell module 100 according to a preferred embodiment of the present invention. FIGS. 1A-1E schematically show plan views and cross sectional views in the steps of the manufacturing process of the solar cell module 100. The cross sectional views are cross sectional views along a line C-C in the plan view and cross sectional views along a line D-D in the plan view.

In step S30, as shown in FIG. 1A, through laser patterning, a slit S1 (in a left and right direction in the figure) which divides a transparent electrode 12 formed over a transparent substrate 10 is formed, and a slit S2 (in an up and down direction in the figure) is formed in a direction perpendicular to the slit S1. The transparent substrate 10 is made of a material which passes light of a wavelength which is used in the photoelectric conversion in the solar cell, and, for example, glass, plastic, or the like may be used. For the transparent electrode 12, a transparent conductive oxide (TCO) in which tin oxide (SnO₂), zinc oxide (ZnO), indium tin oxide (ITO), or the like is doped with tin (Sn), antimony (Sb), fluorine (F), aluminum (Al), or the like may be used.

A laser device for forming the slits S1 and S2 preferably uses YAG laser of a wavelength of 1064 nm. Power of the laser beam emitted from the laser device is adjusted and the laser beam is radiated from the side of the transparent electrode 12 and consecutively scanned in the direction of the slit S1 and the direction of the slit S2 perpendicular to the direction of the slit S1, to form the slits S1 and S2. Alternatively, the laser for forming the slits S1 and S2 may be radiated from the side of the transparent substrate 10.

Because a large number of slits S1 must be formed in order to integrate a large number of solar cells in series, it is also preferable to use a laser device of a multi-emission type in which a plurality of laser beam emission holes are provided at equal spacing along the direction perpendicular to the slit S1. For example, a laser device having 2-5 laser beam emission holes is preferably used. With this configuration, it is possible to rapidly form a large number of slits S1 for integrating a large number of solar cells in series. Because the slit S2 is greater in size than the other slits and a patterning precision of the slit S2 may be lower than that of the other slits, the patterning conditions can be easily set even when the multi-emission type laser device is used.

In step S32, as shown in FIG. 1B, a film of an photoelectric conversion unit 14 is formed covering the transparent electrode 12 and the slits S1 and S2. No particular limitation is imposed on the photoelectric conversion unit 14, and, for example, an amorphous silicon (a-Si) photoelectric conversion unit, a microcrystalline silicon (μc-Si) photoelectric conversion unit, or a tandem structure of these units may be used. The photoelectric conversion unit 14 may be formed through plasma CVD or the like.

In step S34, as shown in FIG. 1C, a slit S3 which divides the photoelectric conversion unit 14 is formed through laser patterning. The slit S3 is formed at a position near the slit S1 and not overlapping the slit S1, along the direction of the slit S1, and to a surface of the transparent electrode 12.

A laser device for forming the slit S3 preferably uses YAG laser of a wavelength of 532 nm (second harmonics). Power of the laser beam emitted from the laser device is adjusted, and the laser beam is radiated from the side of the transparent substrate 10 and scanned in the direction of the slit S3, to form the slit S3.

In step S36, as shown in FIG. 1D, a backside electrode 16 is formed covering the photoelectric conversion unit 14 and the slit S3. For the backside electrode 16, a reflective metal is preferably used. Alternatively, it is also preferable to employ a layered structure of the reflective metal and a transparent conductive oxide (TCO). As the reflective metal, silver (Ag), aluminum (Al), or the like may be used. As the transparent conductive oxide (TCO), tin oxide (SnO₂), zinc oxide (ZnO), indium tin oxide (ITO), or the like may be used.

In step S38, as shown in FIG. 1E, slits S4 and S5 which divide the photoelectric conversion unit 14 and the backside electrode 16 are formed through laser patterning. The slit S4 is formed at a position near the slit S3 and not overlapping the slits S1 and S3, along the direction of the slits S1 and S3, and to a surface of the transparent electrode 12 to divide the photoelectric conversion unit 14 and the backside electrode 16. With this process, a structure is obtained in which a plurality of solar cells are connected in series along the direction of the slit S2. Similarly, the slit S5 is formed in a region where the slit S2 is formed and to the surface of the transparent electrode 12 to divide the photoelectric conversion unit 14 and the backside electrode 16 formed in the slit S2. With the slit S5, solar cells adjacent in the direction of the slit S1 are electrically separated from each other. Because the slit S5 is formed in the region where the slit S2 is formed, laser light can be radiated from the transparent electrode 12, and the slit S5 can be formed consecutively from the formation of the slit S4.

As described, the slits S1, S3, and S4 are formed in order to connect a group of adjacent solar cells in series, and the slits S2 and S5 are formed to set groups of the solar cells, which are connected in series, in parallel to each other. With this configuration, a structure is obtained in which the solar cells adjacent along the direction of the slit S1 are electrically separated from each other and a plurality of groups of solar cells each having a plurality of solar cells connected in series are provided in parallel to each other. The solar cell groups are ultimately connected in parallel, and the solar cell module 100 is formed.

A laser device for forming the slits S4 and S5 preferably uses YAG laser of a wavelength of 532 nm (second harmonics). Power of the laser beam emitted from the laser device is adjusted, and the laser beam is radiated from the side of the transparent substrate 10 and consecutively scanned in the directions of the slits S4 and S5, to form the slits S4 and S5.

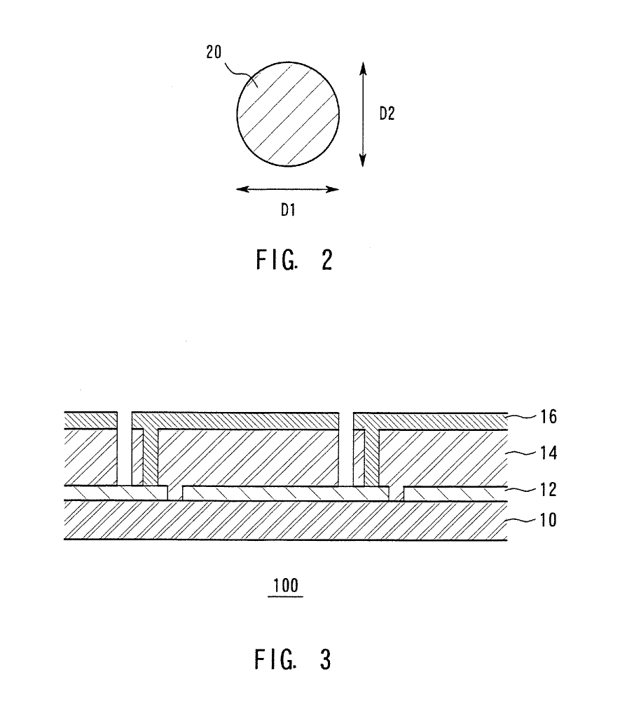

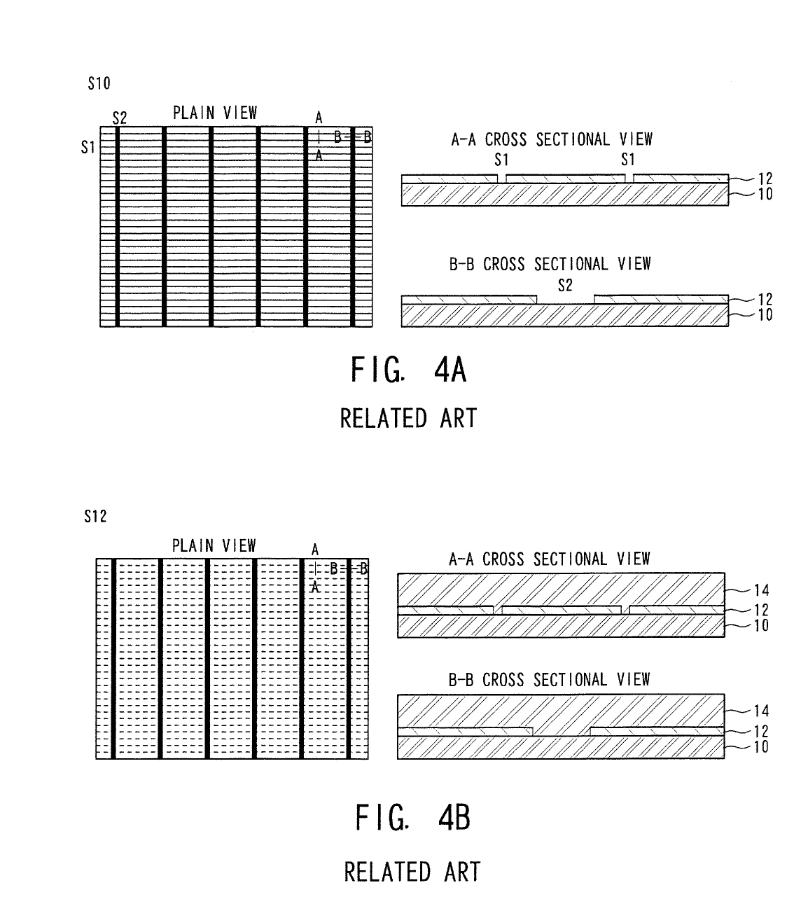

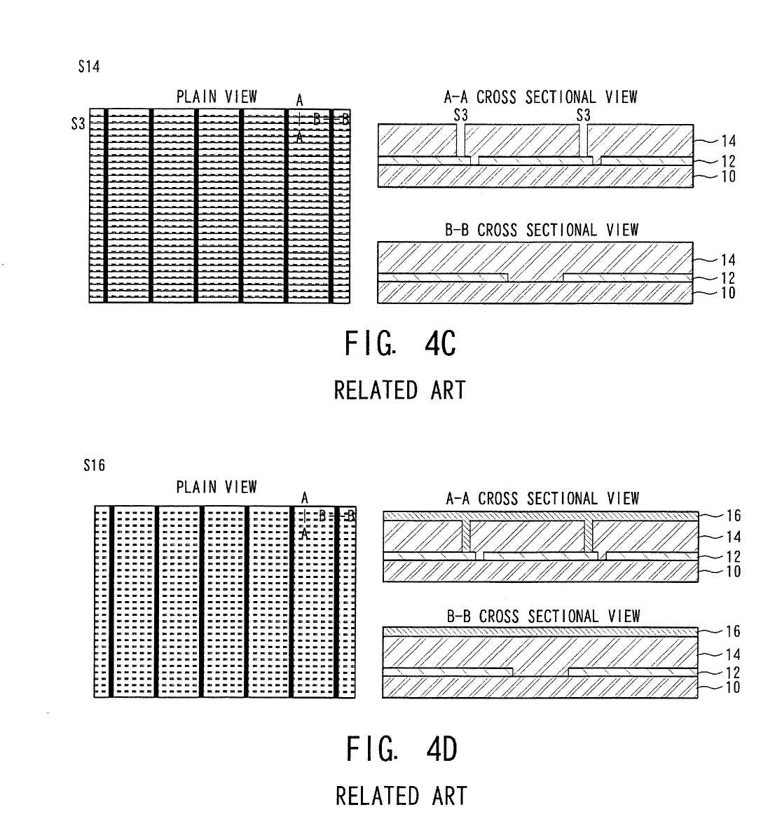

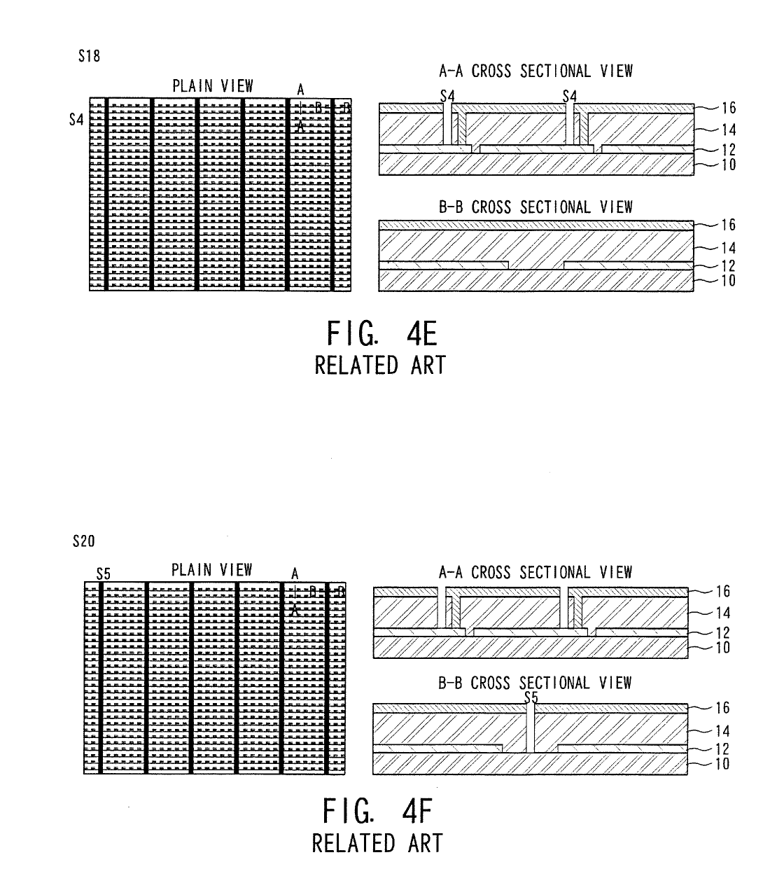

A laser device for forming the slits S4 and S5 radiates a single laser beam having a laser spot where a diameter D1 in a direction along the slit S4 and a diameter D2 in a direction along the slit S5 are approximately equal to each other, as shown in FIG. 2. For example, a laser device having a laser spot of an approximate circular shape or an approximate square shape is used.

With this configuration, the optimum values of the patterning conditions are close to each other between the direction along the slit S4 and the direction perpendicular to this direction and along the slit S5, and, thus, the optimum patterning condition can be easily set in both dividing directions.

In addition, through patterning with a single laser beam, even when the patterning direction is changed, the patterning lines produced by a plurality of laser beams are not overlapped with each other, and the slits S4 and S5 can be easily formed with a single laser device.

Alternatively, steps such as a step for removing an outer peripheral portion of the solar cell module 100 may be provided after step S38.

As described, according to the present embodiment, the laser device does not need to be changed between the time when the slit S4 is formed and the time when the slit S5 is formed, and, thus, the manufacturing process of the overall solar cell module can be simplified. With such a configuration, the time required for the manufacturing can be shortened.

What is claimed is:

1. A method of manufacturing a solar cell module, comprising:
a first step in which a transparent conductive film formed over a substrate is cut using a first laser device in a first direction to form a first channel and in a second direction intersecting the first direction to form a second channel;
a second step in which an photoelectric conversion film formed over the transparent conductive film is cut using a second laser device along the first direction and to a surface of the transparent conductive film to form a third channel; and
a third step in which the photoelectric conversion film and an electrode film formed over the transparent conductive film are cut using a third laser device along the first direction and to the surface of the transparent conductive film to form a fourth channel, and the photoelectric conversion film and the electrode film formed in the second channel are cut using the third laser device along the second direction to form a fifth channel.

2. The method of manufacturing solar cell module according to claim 1, wherein
the third step is executed using a laser device which radiates a laser light with a diameter in a direction along the fourth channel and a diameter in a direction along the fifth channel being approximately equal to each other.

3. The method of manufacturing solar cell module according to claim 1, wherein
in the third step, the fourth channel and the fifth channel are formed by radiating laser light from the side of the substrate.

4. The method of manufacturing solar cell module according to claim 2, wherein
in the third step, the fourth channel and the fifth channel are formed by radiating laser light from the side of the substrate.

5. The method of manufacturing solar cell module according to claim 1, wherein
the first step is executed using a laser device having a plurality of laser beam emission holes provided along the second direction.

6. The method of manufacturing solar cell module according to claim 1, wherein
the second channel is formed in a greater width than the first channel.
